(19) United States
(12) Patent Application Publication
(10) Pub. No.: US 2023/0188114 A1
(43) Pub. Date: Jun. 15, 2023

(54) BULK ACOUSTIC RESONATOR FILTER AND BULK ACOUSTIC RESONATOR FILTER MODULE

(71) Applicant: Samsung Electro-Mechanics Co., Ltd., Suwon-si (KR)

(72) Inventors: Tae Kyung LEE, Suwon-si (KR); Sung Tae KIM, Suwon-si (KR); Kwang Su KIM, Suwon-si (KR); Jae Goon AUM, Suwon-si (KR)

(73) Assignee: Samsung Electro-Mechanics Co., Ltd., Suwon-si (KR)

(21) Appl. No.: 17/875,503

(22) Filed: Jul. 28, 2022

(30) Foreign Application Priority Data
Dec. 14, 2021 (KR) 10-2021-0178704
Apr. 20, 2022 (KR) 10-2022-0048969

(51) Int. Cl. H03H 9/56; H03H 9/205; H03H 9/02

(52) U.S. Cl. CPC H03H 9/566; H03H 9/205; H03H 9/02157

(57) ABSTRACT

A bulk acoustic resonator filter includes a plurality of bulk acoustic resonators connected between first and second radio frequency (RF) ports to form a frequency band, wherein each of the plurality of bulk acoustic resonators includes a first electrode, a second electrode, and a piezoelectric layer disposed between the first and second electrodes, the plurality of bulk acoustic resonators include first and second bulk acoustic resonators having different differences between a resonant frequency and an antiresonant frequency, and different ratios of a thickness of the piezoelectric layer to a total thickness of the first and second electrodes, and/or different thicknesses of the piezoelectric layer.

### CROSS-REFERENCE TO RELATED APPLICATIONS

This application claims the benefit under 35 USC 119(a) of Korean Patent Application Nos. 10-2021-0178704 filed on Dec. 14, 2021, and 10-2022-0048969 filed on Apr. 20, 2022, in the Korean Intellectual Property Office, the entire disclosures of which are incorporated herein by reference for all purposes.

### BACKGROUND

### 1. Field

The present disclosure relates to a bulk acoustic resonator filter and a bulk acoustic resonator filter module.

### 2. Description of Related Art

With the recent rapid development of mobile communication devices, chemical and biological testing devices, demand for small and lightweight filters, oscillators, resonant elements, and acoustic resonant mass sensors used in such devices has increased.

Bulk acoustic resonators may be used to implement such a small and lightweight filter, oscillator, resonator element, and acoustic resonance mass sensor. Compared to dielectric filters, metal cavity filters, and wave guides, the bulk acoustic resonators are very small and have good performance, and therefore may be widely used in communications modules of modern mobile devices requiring good performance (e.g., a high quality factor, a low energy loss, and a wide passband).

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic resonator filter includes a plurality of bulk acoustic resonators connected between a first radio frequency (RF) port and a second RF port to form a frequency band, wherein each of the plurality of bulk acoustic resonators includes a first electrode, a second electrode, and a piezoelectric layer disposed between the first and second electrodes, the plurality of bulk acoustic resonators include at least one first bulk acoustic resonator and at least one second bulk acoustic resonator, a difference between a resonant frequency and an antiresonant frequency of each of the at least one first bulk acoustic resonator is different from a difference between a resonant frequency and an antiresonant frequency of each of the at least one second bulk acoustic resonator, and a ratio of a thickness of the piezoelectric layer to a total thickness of the first and second electrodes in each of the at least one first bulk acoustic resonator is different from a ratio of a thickness of the piezoelectric layer to a total thickness of the first and second electrodes in each of the at least one second bulk acoustic resonator, and/or the thickness of the piezoelectric layer of each of the at least one first bulk acoustic resonator is different from the thickness of the piezoelectric layer of each of the at least one second bulk acoustic resonator.

The at least one first bulk acoustic resonator may include a first series bulk acoustic resonator electrically connected in series between the first and second RF ports, the at least one second bulk acoustic resonator may include a second series bulk acoustic resonator electrically connected in series between the first and second RF ports, the plurality of bulk acoustic resonators may further include at least one shunt bulk acoustic resonator electrically connected between the first and second series bulk acoustic resonators and a ground, and a difference between the antiresonant frequencies of the first and second series bulk acoustic resonators may be less than a difference between resonant frequencies of the first and second series bulk acoustic resonators.

The plurality of bulk acoustic resonators may further include at least one series bulk acoustic resonator electrically connected in series between the first and second RF ports, the at least one first bulk acoustic resonator may include a first shunt bulk acoustic resonator electrically connected between the at least one series bulk acoustic resonator and a ground, the at least one second bulk acoustic resonator may include a second shunt bulk acoustic resonator electrically connected between the at least one series bulk acoustic resonator and the ground, and a difference between the resonant frequencies of the first and second shunt bulk acoustic resonators may be less than a difference between antiresonant frequencies of the first and second shunt bulk acoustic resonators.

The at least one first bulk acoustic resonator may include a first series bulk acoustic resonator electrically connected in series between the first and second RF ports, the at least one second bulk acoustic resonator may include a second series bulk acoustic resonator electrically connected in series between the first and second RF ports; the at least one first bulk acoustic resonator may further may include a first shunt bulk acoustic resonator electrically connected between a ground and either one or both of the first and second series bulk acoustic resonators, and the at least one second bulk acoustic resonator may further may include a second shunt bulk acoustic resonator electrically connected between the ground and either one or both of the first and second series bulk acoustic resonators.

A difference between the antiresonant frequencies of the first and second series bulk acoustic resonators may be less than a difference between resonant frequencies of the first and second series bulk acoustic resonators, and a difference between the resonant frequencies of the first and second shunt bulk acoustic resonators may be less than a difference between antiresonant frequencies of the first and second shunt bulk acoustic resonators.

Each of the first and second shunt bulk acoustic resonators may include an anti-series structure.

A number of the plurality of bulk acoustic resonators may be three or more, the at least one first bulk acoustic resonator may include a first bulk acoustic resonator electrically connected closest to the first RF port among the plurality of bulk acoustic resonators, and the at least one second bulk acoustic resonator may include a second bulk acoustic resonator electrically connected closest to the second RF port among the plurality of bulk acoustic resonators.

A number of the plurality of bulk acoustic resonators may be 5 or more, the at least one first bulk acoustic resonator may further may include a first bulk acoustic resonator electrically connected second closest to the first RF port among the plurality of bulk acoustic resonators, and the at least one second bulk acoustic resonator may further may include a second bulk acoustic resonator electrically connected second closest to the second RF port among the plurality of bulk acoustic resonators.

The at least one first bulk acoustic resonator and the at least one second bulk acoustic resonator may be disposed on a single substrate.

A number of piezoelectric layers of each of the at least one first bulk acoustic resonator may be different from a number of piezoelectric layers of each of the at least one second bulk acoustic resonators.

A piezoelectric material of the piezoelectric layer of each of the at least one first bulk acoustic resonator may be the same as a piezoelectric material of the piezoelectric layer of each of the at least one second bulk acoustic resonator.

A spacing distance between the first electrode and the second electrode of each of the at least one first bulk acoustic resonator may be different from a spacing distance between the first electrode and the second electrode of each of the at least one second bulk acoustic resonator.

The ratio of the thickness of the piezoelectric layer to the total thickness of the first and second electrodes in each of the at least one first bulk acoustic resonator may be greater than the ratio of the thickness of the piezoelectric layer to the total thickness of the first and second electrodes in each of the at least one second bulk acoustic resonator, and/or the thickness of the piezoelectric layer of each of the at least one first bulk acoustic resonator may be greater than the thickness of the piezoelectric layer of each of the at least one second bulk acoustic resonator, and an overlapping area of the first electrode, the piezoelectric layer, and the second electrode of each of the at least one first bulk acoustic resonator may be greater than an overlapping area of the first electrode, the piezoelectric layer, and the second electrode of each of the at least one second bulk acoustic resonator filter.

The ratio of the thickness of the piezoelectric layer to the total thickness of the first and second electrodes in each of the at least one first bulk acoustic resonator may be greater than the ratio of the thickness of the piezoelectric layer to the total thickness of the first and second electrodes in each of the at least one second bulk acoustic resonator, and/or the thickness of the piezoelectric layer of each of the at least one first bulk acoustic resonator may be greater than the thickness of the piezoelectric layer of each of the at least one second bulk acoustic resonator, and each of the at least one first bulk acoustic resonator may include an anti-parallel structure.

The frequency band may cover a portion of a frequency range of 3 GHz or higher and 6 GHz or less.

The first RF port may be electrically connected between the second RF port and a power amplifier, the first bulk acoustic resonator may be electrically connected between the first RF port and the second bulk acoustic resonator, and the ratio of the thickness of the piezoelectric layer to the total thickness of the first and second electrodes in each of the at least one first bulk acoustic resonator may be greater than the ratio of the thickness of the piezoelectric layer to the total thickness of the first and second electrodes in each of the at least one second bulk acoustic resonator, and/or the thickness of the piezoelectric layer of each of the at least one first bulk acoustic resonator may be greater than the thickness of the piezoelectric layer of each of the at least one second bulk acoustic resonator.

In another general aspect, a bulk acoustic resonator filter module includes a first bulk acoustic resonator filter forming a first frequency band and including a first bulk acoustic resonator; and a second bulk acoustic resonator filter forming a second frequency band and including a second bulk acoustic resonator, wherein each of the first and second bulk acoustic resonators includes a first electrode, a second electrode, and a piezoelectric layer disposed between the first and second electrodes, a difference between a resonant frequency and an anti-resonant frequency of the first bulk acoustic resonator is greater than a difference between a resonant frequency and an anti-resonant frequency of the second bulk acoustic resonator, and a ratio of a thickness of the piezoelectric layer to a total thickness of the first and second electrodes in the first bulk acoustic resonator is greater than a ratio of a thickness of the piezoelectric layer to a total thickness of the first and second electrodes in the second bulk acoustic resonator, and/or the thickness of the piezoelectric layer of the first bulk acoustic resonator is greater than the thickness of the piezoelectric layer of the second bulk acoustic resonator.

The first bulk acoustic resonator filter and the second bulk acoustic resonator filter may be configured so that a power of a first RF signal passing through the first bulk acoustic resonator filter is greater than a power of a second RF signal passing through the second bulk acoustic resonator filter.

The first bulk acoustic resonator filter may be electrically connected between a power amplifier and an antenna, and the second bulk acoustic resonator filter may be electrically connected to the antenna.

The first bulk acoustic resonator filter may further include a third bulk acoustic resonator, the third bulk acoustic resonator may include a first electrode, a second electrode, and a piezoelectric layer disposed between the first and second electrodes, the first bulk acoustic resonator may be electrically connected to the third bulk acoustic resonator so that a first RF signal passes through the first bulk acoustic resonator before the first RF signal passes through the third bulk acoustic resonator, and the ratio of the thickness of the piezoelectric layer to the total thickness of the first and second electrodes in the first bulk acoustic resonator may be greater than a ratio of a thickness of the piezoelectric layer to a total thickness of the first and second electrodes in the third bulk acoustic resonator, and/or the thickness of the piezoelectric layer of the first bulk acoustic resonator may be greater than the thickness of the piezoelectric layer of the third bulk acoustic resonator.

The second bulk acoustic resonator filter may further include a fourth bulk acoustic resonator, the fourth bulk acoustic resonator may include a first electrode, a second electrode, and a piezoelectric layer disposed between the first and second electrodes, the fourth bulk acoustic resonator may be electrically connected to the second bulk acoustic resonator so that a second RF signal passes through the fourth bulk acoustic resonator before the second RF signal passes through the second bulk acoustic resonator, and a ratio of a thickness of the piezoelectric layer to a total thickness of the first and second electrodes in the fourth bulk acoustic resonator may be greater than the ratio of the thickness of the piezoelectric layer to the total thickness of the first and second electrodes in the second bulk acoustic resonator, and/or the thickness of the piezoelectric layer thickness of the fourth bulk acoustic resonator may be greater than the thickness of the piezoelectric layer of the second bulk acoustic resonator.

The ratio of the thickness of the piezoelectric layer to the total thickness of the first and second electrodes in the first bulk acoustic resonator may be greater than the ratio of the thickness of the piezoelectric layer to the total thickness of the first and second electrodes in the fourth bulk acoustic resonator, and/or the thickness of the piezoelectric layer of the first bulk acoustic resonator may be greater than the thickness of the piezoelectric layer of the fourth bulk acoustic resonator.

The second bulk acoustic resonator filter may further include a fourth bulk acoustic resonator, the fourth bulk acoustic resonator may include a first electrode, a second electrode, and a piezoelectric layer disposed between the first and second electrodes, the fourth bulk acoustic resonator may be electrically connected to the second bulk acoustic resonator so that a second RF signal passes through the fourth bulk acoustic resonator before the second RF signal passes through the second bulk acoustic resonator, a ratio of a thickness of the piezoelectric layer to a total thickness of the first and second electrodes in the fourth bulk acoustic resonator may be greater than the ratio of the thickness of the piezoelectric layer to the total thickness of the first and second electrodes in the second bulk acoustic resonator, and/or the thickness of the piezoelectric layer of the fourth bulk acoustic resonator may be greater than the thickness of the piezoelectric layer of the second bulk acoustic resonator, and the ratio of the thickness of the piezoelectric layer to the total thickness of the first and second electrodes in the first bulk acoustic resonator may be greater than the ratio of the thickness of the piezoelectric layer to the total thickness of the first and second electrodes in the fourth bulk acoustic resonator, and/or the thickness of the piezoelectric layer of the first bulk acoustic resonator may be greater than the thickness of the piezoelectric layer of the fourth bulk acoustic resonator.

The first bulk acoustic resonator filter may be electrically connected to a first power amplifier, and the second bulk acoustic resonator filter may be electrically connected to a second power amplifier.

The first bulk acoustic resonator filter may be electrically connected to a power amplifier, and the second bulk acoustic resonator filter may be electrically connected to a low noise amplifier.

A center frequency of the first frequency band may be higher than a center frequency of the second frequency band.

Other features and aspects will be apparent from the following detailed description, the drawings, and the claims.

### BRIEF DESCRIPTION OF DRAWINGS

FIGS. 1A through 1E are diagrams illustrating various circuit structures of a bulk acoustic resonator filter according to embodiments in the present disclosure.

FIGS. 2A through 2C are diagrams illustrating various circuit structures of a bulk acoustic resonator filter module according to embodiments in the present disclosure.

FIGS. 3A and 3B are diagrams illustrating bands of a bulk acoustic resonator filter according to an embodiment in the present disclosure.

FIGS. 3C and 3D are diagrams illustrating bands of a bulk acoustic resonator filter module according to an embodiment in the present disclosure.

FIG. 4A is a perspective view illustrating a configuration of a bulk acoustic resonator filter according to an embodiment in the present disclosure.

FIGS. 4B and 4C are perspective views illustrating a configuration of a bulk acoustic resonator filter module according to embodiments in the present disclosure.

FIGS. 5A through 5C are side views illustrating various structures of first and second bulk acoustic resonators of a bulk acoustic resonator filter and a bulk acoustic resonator filter module according to embodiments in the present disclosure.

FIGS. 6A to 6D are side views illustrating various types of RF ports of a bulk acoustic resonator filter and a bulk acoustic resonator filter module according to embodiments in the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

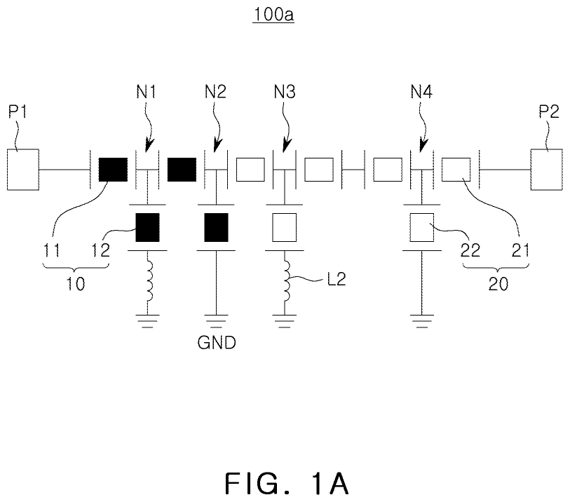

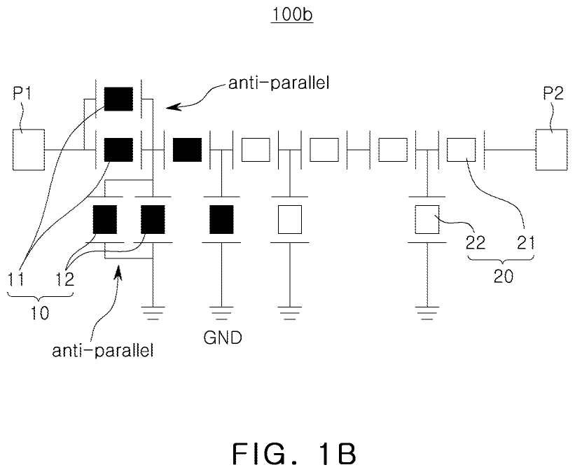

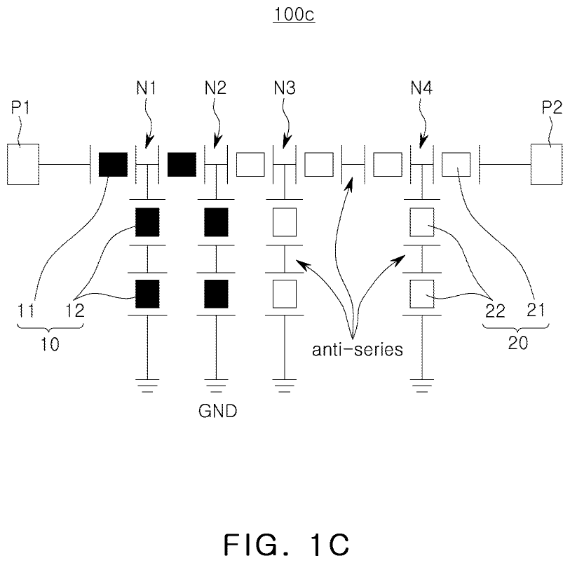

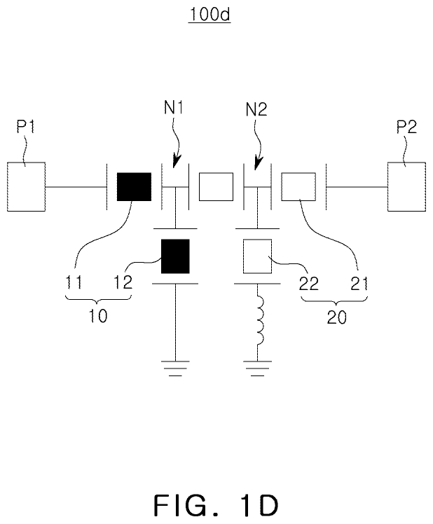

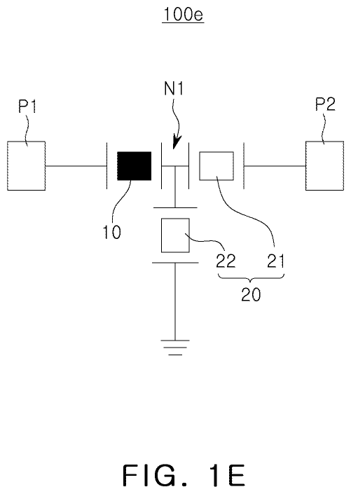

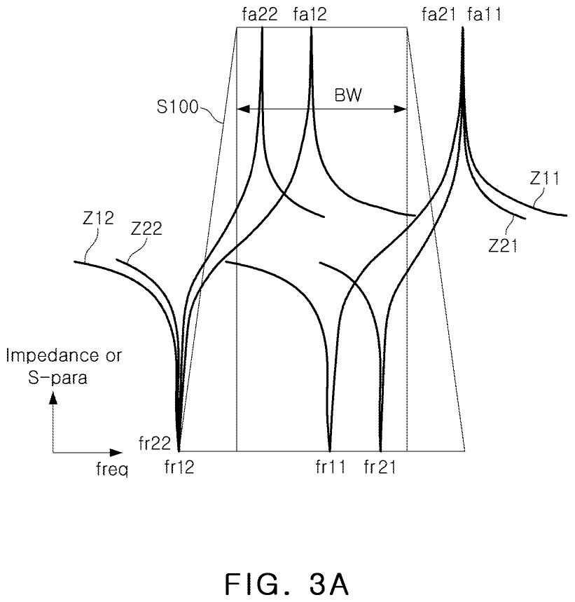

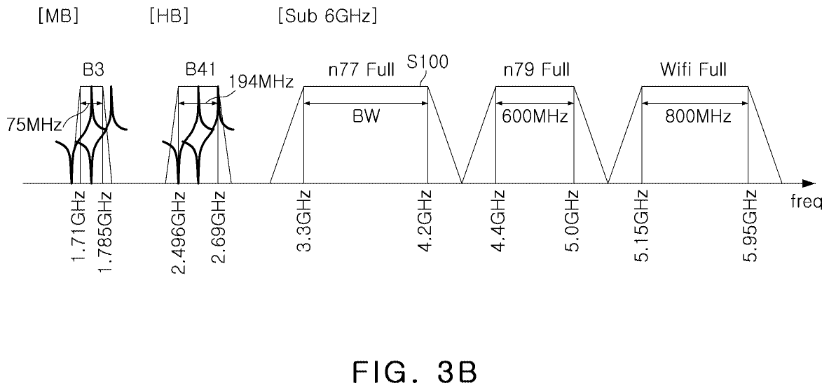

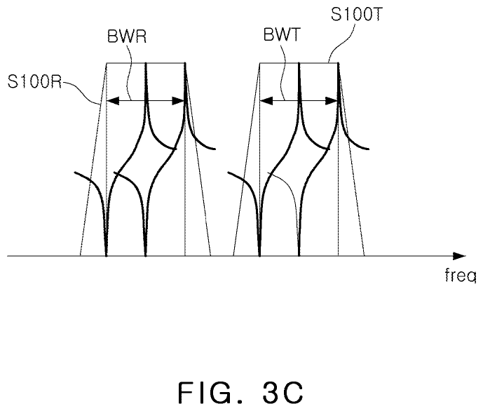

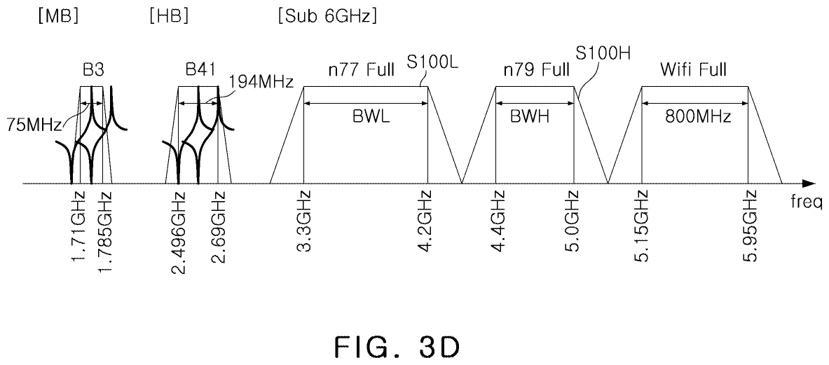

Referring to FIGS. 1A through 1E and 3A, the bulk acoustic resonator filter 100a, 100b, 100c, 100d, or 100e according to embodiments in the present disclosure may include a plurality of bulk acoustic resonators 10 and 20 connected between first and second RF ports P1 and P2 to form a frequency band BW.

When the frequency band BW is a passband, a radio frequency (RF) signal having a fundamental frequency within the frequency band BW may pass between the first and second RF ports P1 and P2, and components (e.g., harmonics and noise) other than the fundamental frequency within the frequency band BW may be blocked between the first and second RF ports P1 and P2.

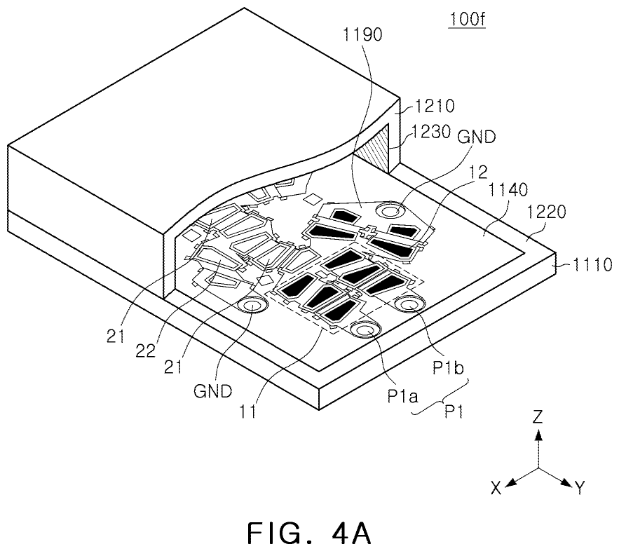

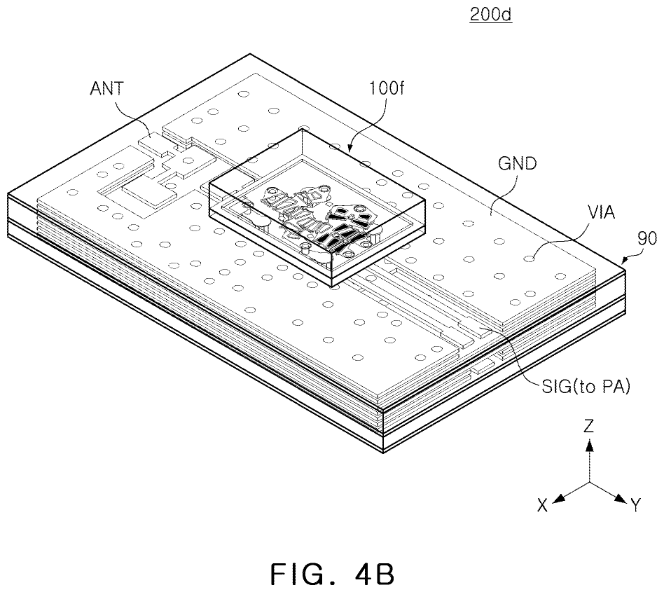

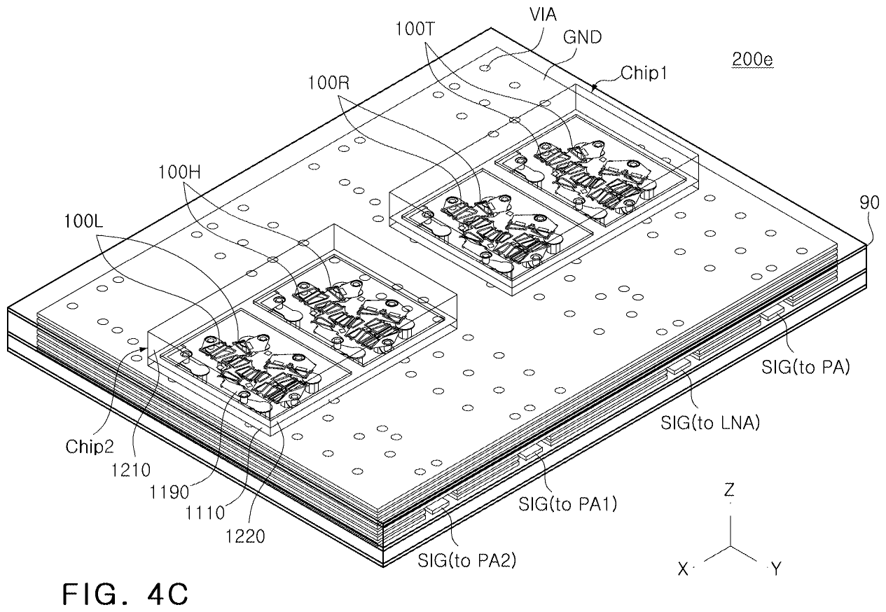

For example, a plurality of branch nodes N1, N2, N3, and N4 between the plurality of bulk acoustic resonators 10 and 20 may be implemented as a metal layer (e.g., 1190 of FIGS. 4A, 4C, 5A to 5C, and 6A to 6D). The metal layer may be implemented with a material having a relatively low resistivity, such as gold (Au), gold-tin (Au—Sn) alloy, copper (Cu), copper-tin (Cu—Sn) alloy, and aluminum (Al), and aluminum alloy, but the present disclosure is not limited thereto.

For example, each of the plurality of bulk acoustic resonators 10 and 20 may be a film bulk acoustic resonator (FBAR) or a solidly mounted resonator (SMR). The FBAR may include a cavity, and the SMR may not include a cavity.

Each of the plurality of bulk acoustic resonators 10 and 20 may have resonant frequencies fr11, fr12, fr21, and fr22 and antiresonant frequencies fa11, fa12, fa21, and fa22 based on piezoelectric characteristics thereof. The antiresonant frequencies fa11, fa12, fa21, and fa22 may be higher than the corresponding resonant frequencies fr11, fr12, fr21, and fr22, and impedances Z11, Z12, Z21, and Z22 of the plurality of bulk acoustic resonators 10 and 20 may approach zero based on an LC series resonance as they approach the corresponding resonant frequencies fr11, fr12, fr21, and fr22, and may approach infinity based on the LC parallel resonance as they approach the corresponding antiresonant frequencies fa11, fa12, fa21, and fa22.

The plurality of bulk acoustic resonators 10 and 20 may include a plurality of series bulk acoustic resonators 11 and 21 and a plurality of shunt bulk acoustic resonators 12 and 22. The plurality of series bulk acoustic resonators 11 and 21 may be electrically connected in series between the first and second RF ports P1 and P2, and the plurality of shunt bulk acoustic resonators 12 and 22 may be electrically connected between the plurality of series bulk acoustic resonators 11 and 21 and a ground GND.

A portion of an energy of an RF signal input to the first RF port P1 may be reflected by the plurality of bulk acoustic resonators 10 and 20 or may be shunted to the ground GND while moving toward the second RF port P2, and the remainder of the energy of the RF signal may pass through the second RF port P2. The ratio of the energy of the RF signal that is reflected by the plurality of bulk acoustic resonators 10 and 20 or that is shunted to the ground GND may be determined based on an impedance relationship between the plurality of series bulk acoustic resonators 11 and 21 and the plurality of shunt bulk acoustic resonators 12 and 22. For example, the ratio may correspond to an S-parameter S100 between the first and second RF ports P1 and P2, and may be measured by a nonlinear vector network analyzer.

When impedances Z11 and Z21 of the plurality of series bulk acoustic resonators 11 and 21 approach zero or when impedances Z12 and Z22 of the plurality of shunt bulk acoustic resonators 12 and 22 approach infinity, most of the energy of the RF signal may pass between the first and second RF ports P1 and P2. When the impedances Z11 and Z21 of the plurality of series bulk acoustic resonators 11 and 21 approach infinity or the impedances Z12 and Z22 of the plurality of shunt bulk acoustic resonators 12 and 22 approach zero, most of the energy of the RF signal may be reflected or shunted to the ground GND.

Accordingly, when the resonant frequencies fr11 and fr21 of the plurality of series bulk acoustic resonators 11 and 21 and the antiresonant frequencies fa12 and fa22 of the plurality of shunt bulk acoustic resonators 12 and 22 fall within the frequency band BW, the plurality of bulk acoustic resonators 10 and 20 may form a passband. When the antiresonant frequencies fa11 and fa21 of the plurality of series bulk acoustic resonators 11 and 21 and the resonant frequencies fr12 and fr22 of the plurality of shunt bulk acoustic resonators 12 and 22 fall within the frequency band BW, the plurality of bulk acoustic resonators 10 and 20 may form a stop band.

For example, the highest frequency and the lowest frequency of the frequency band BW may correspond to a frequency corresponding to a value 10 dB lower than the highest value of an S-parameter in the frequency band BW. The antiresonant frequencies fa11 and fa21 of the plurality of series bulk acoustic resonators 11 and 21 may further increase the rate of change of the S-parameter according to a frequency change at the highest frequency of the frequency band BW, and the resonant frequencies fr12 and fr22 of the plurality of shunt bulk acoustic resonators 12 and 22 may further increase the rate of change of the S-parameter according to a frequency change at the lowest frequency of the frequency band BW. The rate of change of the S-parameter at the lowest frequency and the highest frequency may correspond to a roll-off characteristic, a skirt characteristic, and/or an attenuation characteristic. As the roll-off characteristic, the skirt characteristic, and/or the attenuation characteristic is sharper, a component (e.g., a component based on the synthesis of a harmonic component and a low-frequency component) close to the frequency band BW among the harmonic-based components of the RF signal may be effectively blocked, and the frequency band BW may be closer to an adjacent frequency band and a frequency resource may be used efficiently.

The frequency band BW may be widened as a difference between the resonant frequencies fr11 and fr21 of the plurality of series bulk acoustic resonators 11 and 21 and the antiresonant frequencies fa12 and fa22 of the plurality of shunt bulk acoustic resonators 12 and 22 increases. However, an insertion loss within the frequency band BW may increase as the difference between the resonant frequencies fr11 and fr21 of the plurality of series bulk acoustic resonators 11 and 21 and the antiresonant frequencies fa12 and fa22 of the plurality of shunt bulk acoustic resonators 12 and 22 increases.

As the difference between the resonant frequencies fr11, fr12, fr21, and fr22 and the antiresonant frequencies fa11, fa12, fa21, and fa22 of the plurality of bulk acoustic resonators 10 and 20 increases, a wide passband and a small insertion loss may be obtained efficiently. However, as the difference between the resonant frequencies fr11, fr12, fr21, and fr22 and the antiresonant frequencies fa11, fa12, fa21, and fa22 of the plurality of bulk acoustic resonators 10 and 20 increases, it may be more difficult to obtain a sharp roll-off characteristic, skirt characteristic, and/or attenuation characteristic.

The difference between the resonant frequencies fr11, fr12, fr21, and fr22 and the antiresonant frequencies fa11, fa12, fa21, and fa22 of the plurality of bulk acoustic resonators 10 and 20 may be determined based on kt² (an electromechanical coupling factor), and kt² may be determined based on physical characteristics such as sizes, thicknesses, and shapes of each of the plurality of bulk acoustic resonators 10 and 20.

At least some of the plurality of bulk acoustic resonators 10 and 20 may include a first bulk acoustic resonator 10 and a second bulk acoustic resonator 20 in which a difference between the resonant frequencies fr11, fr12, fr21, and fr22 and the antiresonant frequencies fa11, fa12, fa21, and fa22 are different from each other.

For example, the first bulk acoustic resonator 10 having a large difference between the resonant frequencies fr11 and fr12 and the antiresonant frequencies fa11 and fa12 may effectively broaden the frequency band BW, and the second bulk acoustic resonator 20 having a small difference between the resonant frequencies fr21 and fr22 and the antiresonant frequencies fa21 and fa22 may improve the roll-off characteristic, the skirt characteristic, and/or the attenuation characteristic.

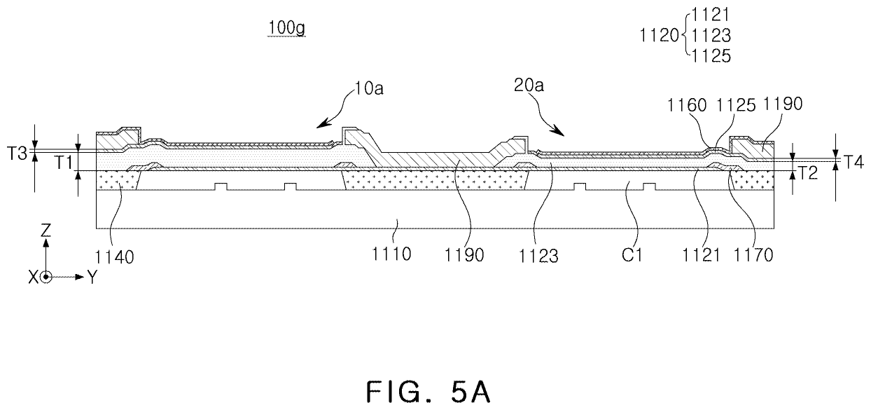

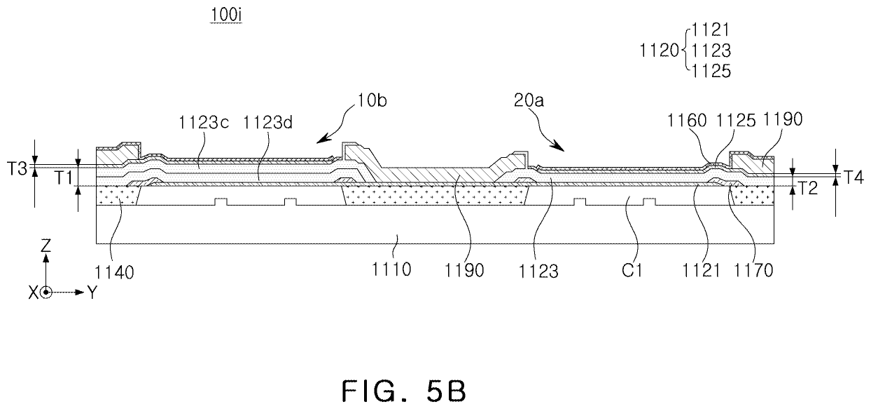

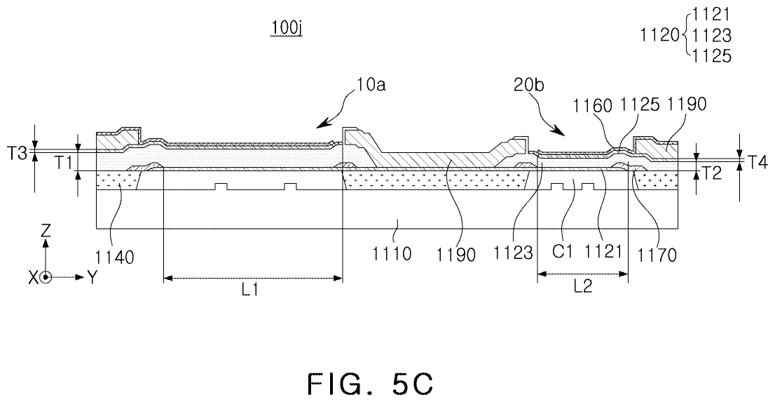

Referring to FIGS. 3A and 5A to 5C, each of the first and second bulk acoustic resonators 10a, 10b, 20a, and 20b may include a resonating unit 1120 including a first electrode 1121, a second electrode 1125, and a piezoelectric layer 1123 disposed between the first and second electrodes 1121 and 1125.

A thickness T1 of the piezoelectric layer 1123 of the first bulk acoustic resonators 10a and 10b may be thicker than a thickness T2 of the piezoelectric layer 1123 of the second bulk acoustic resonators 20a and 20b. Alternatively, a ratio T1/(2*T3) of the thickness T1 of the piezoelectric layer 1123 to a total thickness 2*T3 of the first and second electrodes 1121 and 1125 of the first bulk acoustic resonators 10a and 10b may be greater than a ratio T2/(2*T4) of the thickness T2 of the piezoelectric layer 1123 to a total thickness 2*T4 of the first and second electrodes 1121 and 1125 of the second bulk acoustic resonators 20a and 20b. For example, the thicknesses T1, T2, T3, and T4 may be measured from an image that may be obtained by analysis using any one or any combination of any two or more of a transmission electron microscope, (TEM), an atomic force microscope (AFM), a scanning electron microscope (SEM), an optical microscope, and a surface profiler. Distance values between two points at which pixel values of Z-direction coordinates in each of Y-direction coordinates of the image change may be collected, and the thicknesses T1, T2, T3, and T4 may be measured based on an average value of the collected values.

Accordingly, kt² of the first bulk acoustic resonators 10a and 10b may be greater than kt² of the second bulk acoustic resonators 20a and 20b. For example, a stacked shape of the first electrode 1121, the piezoelectric layer 1123, and the second electrode 1125 may correspond to a capacitor, and a capacitance of the capacitor may decrease as distance between the electrodes in the capacitor increases. Accordingly, as the thicknesses T1 and T2 of the piezoelectric layer 1123 become thicker, the capacitance of the LC parallel resonance of each of the first and second bulk acoustic resonators 10a, 10b, 20a, and 20b may decrease. Since the thicknesses T1 and T2 of the piezoelectric layer 1123 may have a greater influence on the capacitance of the LC parallel resonance than on the capacitance of the LC series resonance of each of the first and second bulk acoustic resonators 10a, 10b, 20a, and 20b, which may affect the difference between the resonant frequencies fr11, fr12, fr21, and fr22 corresponding to the LC series resonance and the antiresonant frequencies fa11, fa12, fa21, and fa22 corresponding to the LC parallel resonance.

For example, since thicknesses T3 and T4 of the second electrode 1125 may affect acoustic impedance of the resonating unit 1120, which may affect a center frequency between the resonant frequencies fr11, fr12, fr21, and fr22 and anti-resonance frequencies fa11, fa12, fa21, and fa22, the thicknesses T3 and T4 may be used as a variable for determining a position of the frequency band BW, and the thicknesses T1 and T2 of the piezoelectric layer 1123 may be used as a variable for adjusting kt² in a state in which the frequency band BW is roughly determined. Accordingly, a ratio T1/(2*T3) of the thickness T1 of the piezoelectric layer to a total thickness 2*T3 of the first and second electrodes in each of the first bulk acoustic resonators 10a and 10b may be different from a ratio T2/(2*T4) of the thickness T2 of the piezoelectric layer to a total thickness 2*T4 in each of the second bulk acoustic resonators 20a and 20b, and/or the thickness T1 of the piezoelectric layer of each of the first bulk acoustic resonators 10a and 10b may be different from the thickness T2 of the piezoelectric layer of each of the second bulk acoustic resonators 20a and 20b.

In addition, as the thicknesses T1 and T2 of the piezoelectric layers 1123 of the first and second bulk acoustic resonators 10a, 10b, 20a, and 20b increase or as the thickness ratios T1/(2*T3) and T2/(2*T4) increase, an electric field formation length between the first and second electrodes 1121 and 1125 of each of the first and second bulk acoustic resonators 10a, 10b, 20a, and 20b may increase, and therefore, a magnitude of an electric field per unit length in the first and second bulk acoustic resonators 10a, 10b, 20a, and 20b when a unit voltage is applied may be weakened. That is, a withstand voltage and/or power durability of the first and second bulk acoustic resonators 10a, 10b, 20a, and 20b may be increased and a low heat dissipation performance may be required.

Since a bandwidth of the frequency band BW may have a characteristic proportional to the center frequency of the frequency band BW, the bandwidth of the frequency band BW may be widened as the center frequency increases. As the center frequency of the frequency band BW increases, a wavelength of an RF signal passing through the first and second bulk acoustic resonators 10a, 10b, 20a, and 20b may be shortened. As the wavelength of the RF signal is shortened, energy attenuation compared to a transmission/reception distance in a remote transmission/reception process at an antenna may increase. That is, as the center frequency of the frequency band BW is higher, greater power may be required for the RF signal in consideration of energy attenuation in the remote transmission/reception process. For example, the RF signal of 5G communication standard may use a relatively higher frequency compared to other communication standards (e.g., LTE) and may be remotely transmitted through the antenna in a state of having greater power (e.g., 26 dBm) compared to power (e.g., 23 dBm) of other communication standards (e.g., LTE). As the power of the RF signal passing through the first and second bulk acoustic resonators 10a, 10b, 20a, and 20b increases, a possibility of damage due to an increase in a voltage applied in which of the first and second bulk acoustic resonators 10a, 10b, 20a, and 20b may increase and heating according to a piezoelectric operation of each of the first and second bulk acoustic resonators 10a, 10b, 20a, and 20b and a possibility of damage due to heating may also increase.

When the thickness T1 or the thickness ratio T1/T3 of the piezoelectric layers of the first bulk acoustic resonators 10a and 10b is greater than the thickness T2 or the thickness ratio T2/T4 of the piezoelectric layers of the second bulk acoustic resonators 20a and 20b, the first bulk acoustic resonators 10a and 10b may not only effectively broaden the frequency band BW but may also improve withstand voltage, power durability, and/or heat dissipation performance. Accordingly, the bulk acoustic resonator filter according to an embodiment in the present disclosure may improve the roll-off characteristic, the skirt characteristic, and/or the attenuation characteristic based on a small kt², may efficiently broaden the frequency band BW based on a large kt², and may improve the withstand voltage, power durability, and/or heat dissipation performance.

Referring back to FIGS. 1A to 1E, the RF signal may move from the first RF port P1 to the second RF port P2, and the energy of the RF signal may gradually decrease due to insertion loss or return loss.

The RF signal may pass through the first bulk acoustic resonator 10 before the second bulk acoustic resonator 20, and the energy of the RF signal may be higher when passing through the first bulk acoustic resonator 10 than when passing through the second bulk acoustic resonator 20.

Since the thickness or thickness ratio of the piezoelectric layer of the first bulk acoustic resonator 10 may be greater than that of the second bulk acoustic resonator 20, the withstand voltage, power durability, and/or heat dissipation performance of the first bulk acoustic resonator 10 may be higher than those of the second bulk acoustic resonator 20, and the RF signal may first pass through the first bulk acoustic resonator 10 having higher withstand voltage, power durability, and/or heat dissipation performance and then pass through the second bulk acoustic resonator 20 having relatively lower withstand voltage, power durability, and/or heat dissipation performance.

Accordingly, even if the thickness or thickness ratio of the piezoelectric layer of some of the plurality of bulk acoustic resonators 10 and 20 of the bulk acoustic resonator filters 100a, 100b, 100c, 100d, and 100e according to embodiments in the present disclosure is high, the overall withstand voltage, power durability, and/or heat dissipation performance of the bulk acoustic resonator filters 100a, 100b, 100c, 100d, and 100e may be efficiently improved.

Referring to FIG. 1A, the bulk acoustic resonator filter 100a according to an embodiment in the present disclosure may include shunt inductors L2 electrically connected in series between the plurality of series bulk acoustic resonators 11 and 21 and the ground GND. The shunt inductors L2 may be electrically connected in series with the plurality of shunt bulk acoustic resonators 12 and 22 so that inductance of the LC series resonance of the plurality of shunt bulk acoustic resonators 12 and 22 may be increased and a resonant frequency corresponding to the LC series resonance may be lowered. Accordingly, the shunt inductors L2 may be used to further broaden the frequency band of the bulk acoustic resonator filter 100a. However, referring to FIGS. 1B, 1C and 1E, the shunt inductor may be omitted.

Referring to FIG. 1B, each of a first series bulk acoustic resonator 11 and a first shunt bulk acoustic resonator 12 of the bulk acoustic resonator filter 100b according to an embodiment in the present disclosure may be connected in an anti-parallel structure. The first electrode and the second electrode of one of the plurality of bulk acoustic resonators connected in the anti-parallel structure may be respectively connected to the second electrode and the first electrode of the other. For example, the first electrode (or the second electrode) of one of the plurality of bulk acoustic resonators and the second electrode (or the first electrode) of the other may be connected through a metal layer formed of the same material as the metal layer of a plurality of branch nodes N1, N2, N3, and N4.

Since the anti-parallel structure may cancel out even order harmonics of the RF signal, linearity characteristics (e.g., IMD2, IP2, P1dB, THD) of the bulk acoustic resonator filter 100b may be improved. In addition, since the anti-parallel structure may distribute the energy of the RF signal in parallel, the withstand voltage, power durability, and/or heat dissipation performance of the bulk acoustic resonator filter 100b may be further improved.

Referring to FIG. 1C, each of the first shunt bulk acoustic resonator 12 and the second shunt bulk acoustic resonator 22 of the bulk acoustic resonator filter 100c according to an embodiment in the present disclosure may be connected in an anti-series structure. In the anti-series structure, the first electrode of one of the plurality of bulk acoustic resonators is connected to the first electrode of the other or may be connected through a metal layer.

Since the anti-series structure may cancel out even order harmonics of the RF signal, linearity characteristics (e.g., IMD2, IP2, P1dB, THD) of the bulk acoustic resonator filter 100c may be improved. In addition, since the anti-series structure may divide a voltage of the RF signal, the withstand voltage, power durability, and/or heat dissipation performance of the bulk acoustic resonator filter 100c may be further improved.

Referring to FIGS. 1D and 1E, the number of first and second bulk acoustic resonators 10 and 20 of the bulk acoustic resonator filters 100d and 100e according to embodiments in the present disclosure may be further reduced and may vary depending on the performance or use required for the bulk acoustic resonator filters 100d and 100e. For example, the bulk acoustic resonator filters 100d and 100e may be used in mobile electronic devices that require a lower level of performance than stationary electronic devices in which the bulk acoustic resonator filter 100a of FIG. 1A is used.

Referring to FIG. 1E, a number of the first bulk acoustic resonator 10 of the bulk acoustic resonator filter 100e according to an embodiment in the present disclosure may be reduced to one according to a design. Although not illustrated in FIG. 1E, a number of the second bulk acoustic resonator 20 may also be reduced to one according to a design.

Referring to FIGS. 1A to 1E, a number of the plurality of bulk acoustic resonators 10 and 20 of the bulk acoustic resonator filters 100a, 100b, 100c, 100d, and 100e according to embodiments in the present disclosure may be three or more, the first bulk acoustic resonator 10 may include a bulk acoustic resonator electrically connected closest to the first RF port P1 among the plurality of bulk acoustic resonators 10 and 20, and the second bulk acoustic resonator 20 may include a bulk acoustic resonator electrically connected closest to the second RF port P2 among the plurality of bulk acoustic resonators 10 and 20.

Referring to FIGS. 1A to 1D, the number of the plurality of bulk acoustic resonators 10 and 20 of the bulk acoustic resonator filters 100a, 100b, 100c, and 100d according to embodiments in the present disclosure may be five or more, the first bulk acoustic resonator 10 may further include a bulk acoustic resonator electrically connected to be first and second closest to the first RF port P1 among the plurality of bulk acoustic resonators 10 and 20, and the second bulk acoustic resonator 20 may further include a bulk acoustic resonator electrically connected to be first and second closest to the second RF port P2 among the plurality of bulk acoustic resonators 10 and 20.

One of the bulk acoustic resonators electrically connected to be first and second closest may be series bulk acoustic resonators 11 and 21 and the other may be shunt bulk acoustic resonators 12 and 22, and the bulk acoustic resonators electrically connected to be first and second closest may form a unit filter stage. The energy of the RF signal may decrease stepwise as the RF signal passes through the unit filter stages. The second bulk acoustic resonator 20 may be positioned to allow the RF signal having energy reduced by at least one unit filter stage to pass therethrough, and thus may have a smaller kt², and the roll-off characteristic, the skirt characteristics and/or the attenuation characteristic may be further improved based on the smaller kt².

The first bulk acoustic resonators 10 may include a first series bulk acoustic resonator 11 electrically connected in series between the first and second RF ports P1 and P2, the second bulk acoustic resonators 20 may include a second series bulk acoustic resonator 21 electrically connected in series between the first and second RF ports P1 and P2, the first bulk acoustic resonators 10 may include the first shunt bulk acoustic resonator 12 electrically connected between the first and second series bulk acoustic resonators 11 and 21 and the ground GND, and the second bulk acoustic resonators 20 may include the second shunt bulk acoustic resonator 22 electrically connected between the first and second series bulk acoustic resonators 11 and 21 and the ground GND.

Referring to FIGS. 1A to 1D and 3A, a difference between the antiresonant frequencies fa11 and fa21 of the first and second series bulk acoustic resonators 11 and 21 may be less than a difference between the resonant frequencies fr11 and fr21 of the first and second series bulk acoustic resonators 11 and 21. Accordingly, the frequency band BW may be efficiently widened at the highest frequency, and the roll-off characteristic, the skirt characteristic, and/or the attenuation characteristic at the highest frequency may be efficiently improved.

Referring to FIGS. 1A to 1D and 3A, a difference between the resonant frequencies fr12 and fr22 of the first and second shunt bulk acoustic resonators 12 and 22 may be less than a difference between the antiresonant frequencies fa12 and fa22 of the first and second shunt bulk acoustic resonators 12 and 22. Accordingly, the frequency band BW may be efficiently widened at the lowest frequency, and the roll-off characteristic, the skirt characteristic, and/or the attenuation characteristic at the lowest frequency may be efficiently improved.

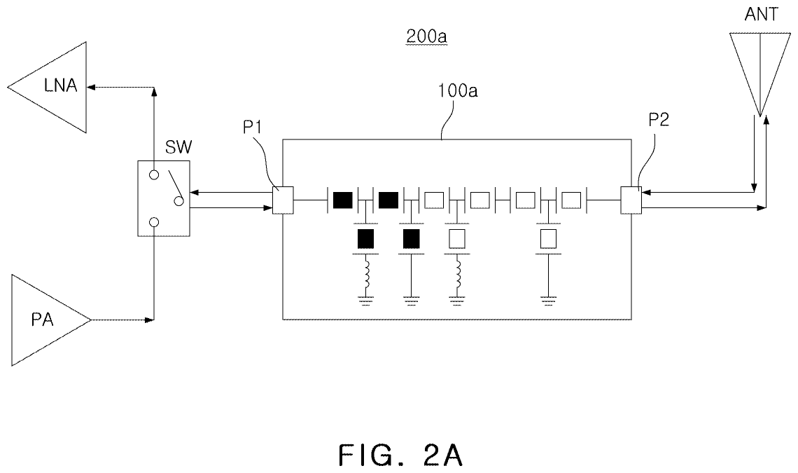

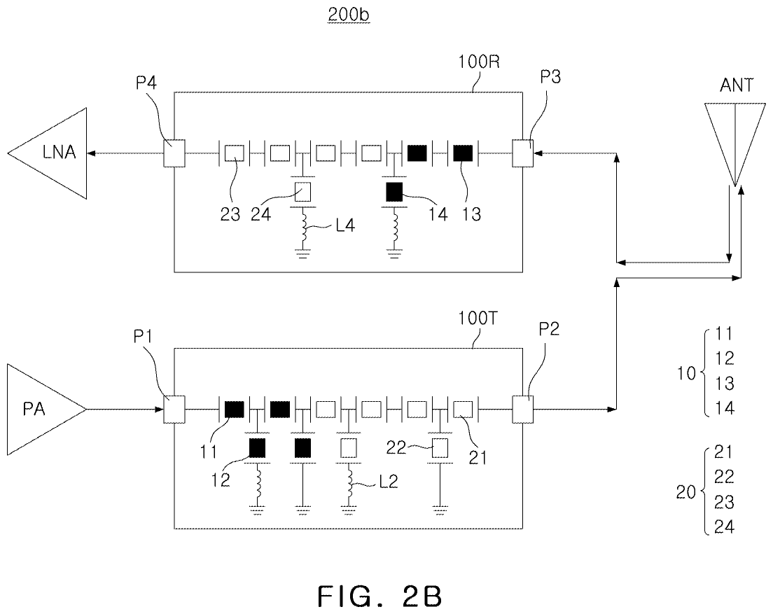

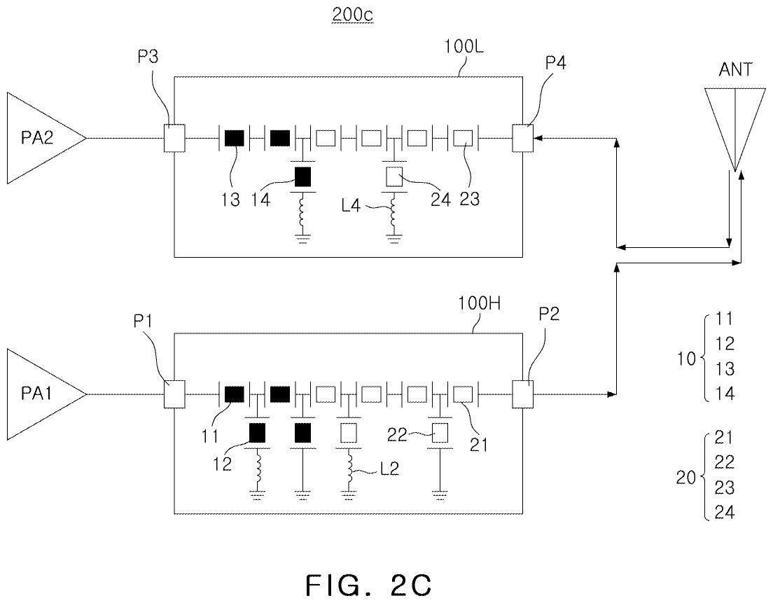

Referring to FIG. 2A, a bulk acoustic resonator filter module 200a according to an embodiment in the present disclosure may include the bulk acoustic resonator filter 100a according to an embodiment in the present disclosure, and the first RF port P1 of the bulk acoustic resonator filter 100a may be electrically connected between the second RF port P2 and a power amplifier PA.

Since the power amplifier PA may finally amplify the RF signal to be remotely transmitted through the antenna ANT, the energy of the RF signal output from the power amplifier PA may be the largest in the bulk acoustic resonator filter module 200a. The bulk acoustic resonator filter 100a may be disposed such that the RF signal first passes through the first bulk acoustic resonator having a greater piezoelectric layer thickness or thickness ratio before the second bulk acoustic resonator, so that a withstand voltage, power durability, and/or heat dissipation performance may be improved efficiently.

For example, the bulk acoustic resonator filter 100a may be used for both an RF signal remotely transmitted by the antenna ANT and an RF signal remotely received by the antenna ANT, and an RF switch SW may be electrically connected between the bulk acoustic resonator filter 100a and the power amplifier PA and may be electrically connected between the bulk acoustic resonator filter 100a and a low noise amplifier LNA. The low-noise amplifier LNA may initially amplify an RF signal remotely received by an antenna ANT.

For example, the RF switch SW may be electrically connected to one of the power amplifier PA and the low noise amplifier LNA by a time division duplexing (TDD) method, and a connection target of the RF switch SW may be changed periodically. For example, the RF switch SW may have a single pole double throw (SPDT) structure.

Since an energy of the remotely transmitted RF signal may be greater than an energy of the remotely received RF signal, the bulk acoustic resonator filter 100a may be configured such that the first bulk acoustic resonator having a large piezoelectric layer thickness or thickness ratio is connected toward the RF switch SW, even if the TDD method is used.

Referring to FIG. 3B, the bulk acoustic resonator filter 100a according to an in the present disclosure may form a frequency band (e.g., a portion of 3 GHz or higher and 6 GHz or less) requiring a center frequency higher than that of other communication standards (e.g., B3 band and B41 band of LTE) such as the n77 band of the 5G communication standard and broader bandwidth, and may form a close frequency band BW for an adjacent frequency band such as the n79 band. Depending on the design, the frequency band BW of the bulk acoustic resonator filter 100a may be designed to form a frequency band other than the n77 band.

Referring to FIGS. 2B and 2C, the bulk acoustic resonator filter modules 200b and 200c according to embodiments in the present disclosure may include first bulk acoustic resonator filters 100T and 100H and second bulk acoustic resonator filters 100R and 100L. The first bulk acoustic resonator filters 100T and 100H may be implemented in the same manner as the bulk acoustic resonator filters 100a, 100b, 100c, 100d, and 100e of FIGS. 1A to 1E, and the second bulk acoustic resonator filter 100R and 100L may also be implemented substantially similar to the bulk acoustic resonator filters 100a, 100b, 100c, 100d, and 100e. For example, the shunt inductor L4 may be the same as the shunt inductor L2 of FIG. 1A.

The first bulk acoustic resonator filters 100T and 100H may include the first bulk acoustic resonators 11 and 12 and the second bulk acoustic resonators 21 and 22, and the second bulk acoustic resonator filters 100R and 100L may include at least one of the first bulk acoustic resonators 13 and 14 and the second bulk acoustic resonators 23 and 24.

The thickness or thickness ratio (piezoelectric layer to electrode) of the piezoelectric layer of the first bulk acoustic resonators 11 and 12 of the first bulk acoustic resonator filters 100T and 100H may be higher than the thickness or thickness ratio of the piezoelectric layer of the bulk acoustic resonators 23 and 24 of the second bulk acoustic resonator filters 100R and 100L.

Accordingly, the first bulk acoustic resonator filters 100T and 100H may have higher withstand voltage, power durability, and/or heat dissipation performance than the second bulk acoustic resonator filters 100R and 100L. For example, the first bulk acoustic resonator filters 100T and 100H may be configured such that a first RF signal having a power greater than that of a second RF signal passing through the second bulk acoustic resonator filters 100R and

Referring to FIG. 2B, the first bulk acoustic resonator filter 100T may be electrically connected to the power amplifier PA, and the second bulk acoustic resonator filter 100R may be electrically connected to the low noise amplifier LNA. Since energy of the first RF signal amplified by the power amplifier PA may be greater than energy of the second RF signal remotely received from the antenna ANT, the first bulk acoustic resonator filter 100T may require higher withstand voltage, power durability, and/or heat dissipation performance. The first bulk acoustic resonator filter 100T and the second bulk acoustic resonator filter 100R may have different frequency bands using a frequency division duplexing (FDD) method.

Referring to FIG. 3C, an S-parameter S100T of the first bulk acoustic resonator filter may have a first frequency band BWT and an S-parameter S100R of the second bulk acoustic resonator filter may have a second frequency band BWR. A center frequency of the first frequency band BWT may be higher than a center frequency of the second frequency band BWR.

Referring to FIG. 2C, the first bulk acoustic resonator filter 100H may be electrically connected to a first power amplifier PA1, and the second bulk acoustic resonator filter 100L may be electrically connected to a second power amplifier PA2. The first and second bulk acoustic resonator filters 100H and 100L may have different frequency bands, and the first RF signal amplified by the first power amplifier PA1 may require greater energy based on a high frequency, compared to the second RF signal amplified by the second power amplifier PA2. That is, the first bulk acoustic resonator filter 100H may require higher withstand voltage, power durability, and/or heat dissipation performance.

Referring to FIG. 3D, the S-parameter S100H of the first bulk acoustic resonator filter may have a first frequency band BWH, and the S-parameter S100L of the second bulk acoustic resonator filter may have a second frequency band BWL. A center frequency of the first frequency band BWH may be higher than a center frequency of the second frequency band BWL. For example, each of the first and second frequency bands BWH and BWL may cover a portion of a frequency range of 3 GHz or higher and 6 GHz or less, but is not limited thereto.

The bulk acoustic resonator filter modules 200b and 200c according to embodiments in the present disclosure may include first and second bulk acoustic resonator filters 100T, 100H, 100R, and 100L in which a withstand voltage, power durability, and/or optimal performance of heat dissipation performance are different from each other may be improved efficiently, and thus a withstand voltage, power durability, and/or heat dissipation performance may be improved efficiently.

Referring to FIGS. 2B and 2C, the first bulk acoustic resonator filters 100T and 100H may be electrically connected between the power amplifiers PA and PA1 and the antenna ANT, and the second bulk acoustic resonator filters 100R and 100L may be electrically connected to the antenna ANT.

That is, since the antenna ANT may be commonly used for the first bulk acoustic resonator filters 100T and 100H and the second bulk acoustic resonator filters 100R and 100L, the first frequency band of the first bulk acoustic resonator filters 100T and 100H and the second frequency band of the second bulk acoustic resonator filters 100R and 100L may be located close to each other. The bulk acoustic resonator filter modules 200b and 200c according to embodiments in the present disclosure may also have a sharp roll-off characteristic, a skirt characteristic, and/or an attenuation characteristic based on the second bulk acoustic resonators 21, 22, 23, and 24 having a relatively small kt².

Referring to 2B and 2C, the thickness or thickness ratio (piezoelectric layer to electrode) of the piezoelectric layer of the first bulk acoustic resonators 11 and 12 of the first bulk acoustic resonator filters 100T and 100H may be higher than that of the first bulk acoustic resonators 13 and 14 of the second bulk acoustic resonator filters 100R and 100L.

For example, the thickness or thickness ratio of the overall piezoelectric layers of the first and second bulk acoustic resonators 11, 12, 21, and 22 of the first bulk acoustic resonator filters 100T and 100H may be higher than that of the first and second bulk acoustic resonators 13, 14, 23, and 24 of the second bulk acoustic resonator filters 100R and 100L. The second bulk acoustic resonators 21 and 22 may be defined as a third bulk acoustic resonator, and the first bulk acoustic resonators 13 and 24 may be defined as a fourth bulk acoustic resonator.

Accordingly, the bulk acoustic resonator filter modules 200b and 200c according to embodiments in the present disclosure may further increase the difference between the withstand voltage, power durability, and/or heat dissipation performance of the first bulk acoustic resonator filters 100T and 100H and those of the second bulk acoustic resonator filters 100R and 100L, and even if the difference between the withstand voltage, power durability, and/or heat dissipation performance required by the first and second communication standards corresponding to the first and second frequency bands is significant, overall withstand voltage, power durability, and/or heat dissipation performance may be stably secured.

The thickness or thickness ratio (piezoelectric layer to electrode) of the piezoelectric layers of the first bulk acoustic resonators 13 and 14 of the second bulk acoustic resonator filters 100R and 100L may be higher than that of the second bulk acoustic resonators 23 and 24. Referring to FIG. 2B, the second bulk acoustic resonator filter 100R may be disposed such that the RF signal remotely received from the antenna ANT passes through the first bulk acoustic resonators 13 and 14 before the second bulk acoustic resonators 23 and 24. Referring to FIG. 2C, the second bulk acoustic resonator filter 100L may be disposed such that the RF signal amplified by the second power amplifier PA2 passes through the first bulk acoustic resonators 13 and 14 before the second bulk acoustic resonators 23 and 24. The first bulk acoustic resonators 13 and 14 may be defined as fourth bulk acoustic resonators.

Referring to FIGS. 4A and 4B, the bulk acoustic resonator filter 100f according to an embodiment in the present disclosure may further include a substrate 1110 and a cap 1210 and may be disposed on an electronic device substrate 90.

The first bulk acoustic resonators 11 and 12 and the second bulk acoustic resonators 21 and 22 may be connected to each other through a metal layer 1190, may be connected to the first RF port P1 or the second RF port P2 or the ground GND, and may be disposed between the substrate 1110 and the cap 1210. For example, each of the first bulk acoustic resonators 11 and 12 and the second bulk acoustic resonators 21 and 22 may have an irregular polygonal shape, and the irregular polygonal may be in the form of the resonating unit 1120 of FIGS. 5A to 5C.

For example, the first RF port P1 may include a plurality of first RF ports P1a and P1b, and may be in the form of a via passing through the substrate 1110. For example, the ground GND may also be in the form of a via. The first RF port P1 and the ground GND may be exposed to the lower surface of the substrate 1110 or may be connected to a pad that may be disposed on a lower surface of the substrate 1110, and may be electrically connected to a wiring of the electronic device substrate 90.

A portion of the wiring may be electrically connected to the antenna ANT, and another portion SIG of the wiring may be electrically connected to the power amplifier PA. A portion of the wiring and the other portion SIG may be surrounded by the ground GND of the electronic device substrate 90. The ground GND of the electronic device substrate 90 may include a plurality of planes containing a metal material, and the plurality of planes may be connected in a Z direction through an interlayer via VIA.

For example, the cap 1210 may contain an insulating material such as glass or silicon, and the cap 1210 may have a U shape in terms of a cross-section perpendicular to an X-Y plane, so that an outer portion of the cap 1210 may protrude downward (e.g., in a −Z direction) compared to the center of the cap 1210. Although FIG. 4A illustrates a shape in which the cap 1210 is cut in half, the cap 1210 may be in the shape of a cap without being cut.

An internal space surrounded by the cap 1210 may be filled with air, and may be disconnected from the outside of the cap 1210 by coupling the cap 1210 and the substrate 1110. A coupling member 1220 may couple the cap 1210 and the substrate 1110, and when an additional structure (e.g., a support layer 1140 or a membrane layer) is disposed between the cap 1210 and the substrate 1110, at least one surface of the coupling member 1220 may be bonded to the additional structure to provide a coupling force between the cap 1210 and the substrate 1110.

The coupling member 1220 may provide a coupling force between the substrate 1110 and the cap 1210. For example, the coupling member 1220 may have a structure in which a plurality of conductive rings are eutectic-bonded or may have an anodic bonding structure, may be formed to seal (hermetic) a space between the substrate 1110 and the cap 1210, and may disconnect the space and the outside from each other.

For example, the coupling member 1220 may be disposed closer to the outside than the first bulk acoustic resonators 11 and 12 and the second bulk acoustic resonators 21 and 22, may surround the first bulk acoustic resonators 11 and 12 and the second bulk acoustic resonators 21 and 22, and may be electrically connected to the ground GND.

For example, the cap 1210 may include a shield layer 1230 disposed on an inner surface and a lower surface thereof, and the shield layer 1230 may contain a metal material and be electrically connected to the coupling member 1220.

Referring to FIGS. 4B and 4C, the bulk acoustic resonator filter modules 200d and 200e according to embodiments in the present disclosure may include the bulk acoustic resonator filter 100f or the first bulk acoustic resonator filters 100T and 100H and the second bulk acoustic resonator filters 100R and 100L.

For example, a first bulk acoustic resonator package Chip1 may include the first bulk acoustic resonator filter 100T and the second bulk acoustic resonator filter 100R, and a second bulk acoustic resonator package Chip2 may include the first bulk acoustic resonator filter 100H and the second bulk acoustic resonator filter 100L. The first and second bulk acoustic resonator packages Chip1 and Chip2 may be spaced apart from each other, and each of the first and second bulk acoustic resonator packages Chip1 and Chip2 may have a structure in which the substrate 1110 and the cap 1210 illustrated in FIG. 4A are coupled to each other.

FIG. 4C illustrates a structure in which the first and second bulk acoustic resonator filters 100T and 100R are integrated into the first bulk acoustic resonator package Chip1, and the first and second bulk acoustic resonator filters 100H and 100L are integrated into the second acoustic resonator package Chip2, but the first and second bulk acoustic resonator filters 100T and 100R may be separately disposed in a plurality of different bulk acoustic resonator packages, and the first and second bulk acoustic resonator filters 100H and 100L may also be separately disposed in a plurality of different bulk acoustic resonator packages. Similarly, the first bulk acoustic resonator filters 100T and 100H may be integrated into a single bulk acoustic resonator package, and the second bulk acoustic resonator filters 100R and 100L may also be integrated into a single bulk acoustic resonator package.

The first bulk acoustic resonator filter 100T may be electrically connected to the power amplifier PA through the wiring SIG of the electronic device substrate 90, the second bulk acoustic resonator filter 100R may be electrically connected to the low-noise amplifier LNA through the wiring SIG of the electronic device substrate 90, the first bulk acoustic resonator filter 100H may be electrically connected to the first power amplifier PA1 through the wiring SIG of the electronic device substrate 90, and the second bulk acoustic resonator filter 100L may be electrically connected to the second power amplifier PA2 through the wiring SIG of the electronic device substrate 90. FIG. 4C does not illustrate a structure in which the first and second bulk acoustic resonator filters 100R, 100L, 100T, and 100H are electrically connected to the antenna, but the structure electrically connected to the antenna ANT illustrated in FIG. 4B may be added to the bulk acoustic resonator filter module 200e of FIG. 4C.

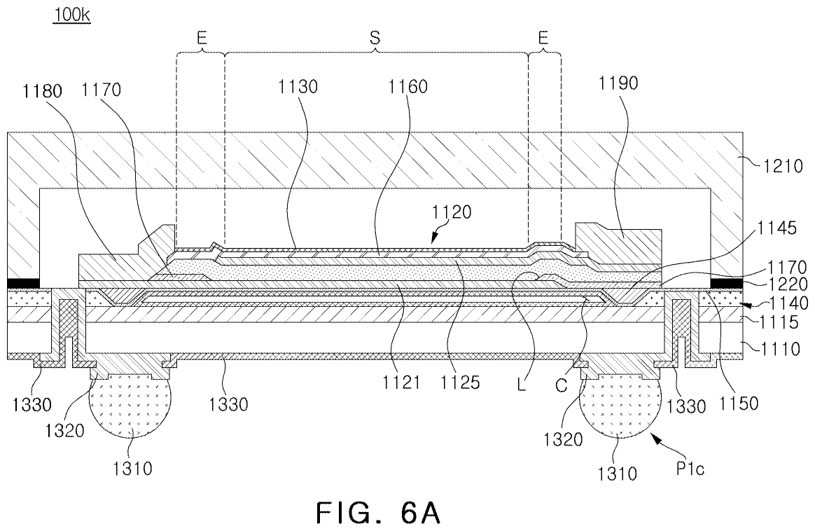

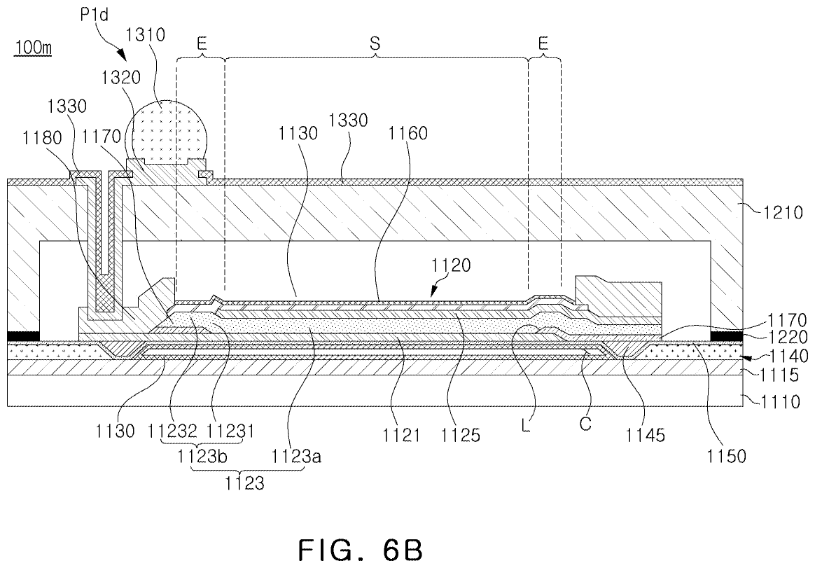

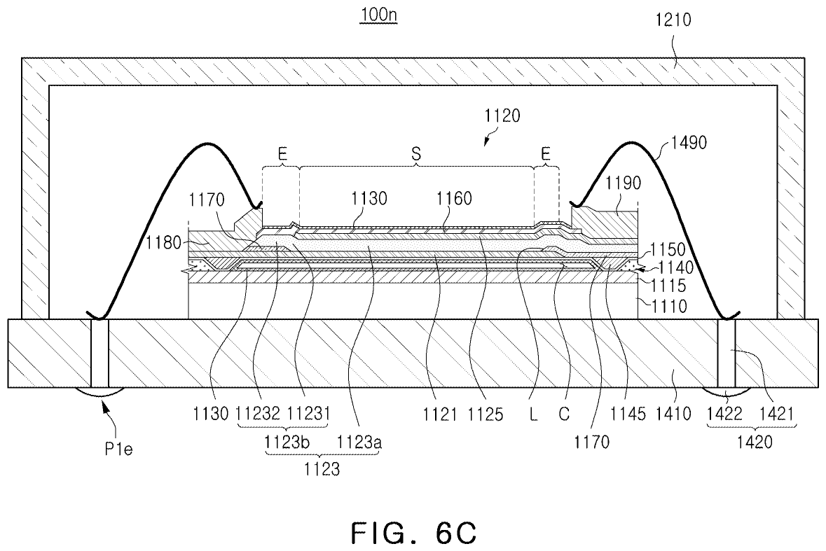

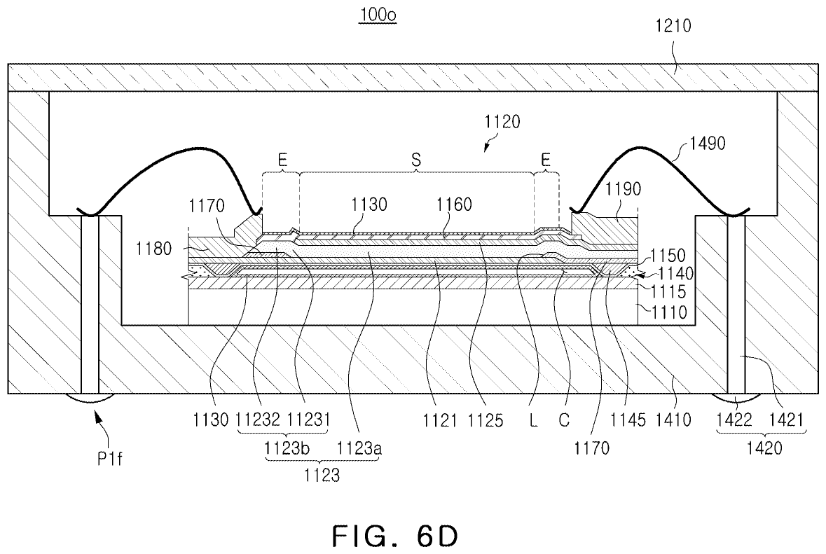

FIGS. 5A to 5C illustrate a Y-Z cross-section of one of the first bulk acoustic resonators 11 and 12 and one of the second bulk acoustic resonators 21 and 22 illustrated together in FIG. 4A taken along a Y-Z plane and viewed in an X direction, and FIGS. 6A to 6D illustrate more specific structures of bulk acoustic resonator filters 100k, 100m, 100n, and 100o according to embodiments in the present disclosure.

Referring to FIGS. 5A to 5C, bulk acoustic resonator filters 100g, 100i, and 100j according to embodiments in the present disclosure may include the first bulk acoustic resonators 10a and 10b and second bulk acoustic resonators 20a and 20b, each of the first and second bulk acoustic resonators 10a, 10b, 20a, and 20b may include a resonating unit 1120, and the resonating unit 1120 may include a first electrode 1121, a piezoelectric layer 1123, and a second electrode 1125.

Referring to FIGS. 5A to 6D, the bulk acoustic resonator filter 100g, 100i, 100j, 100k, 100m, 100n, or 100o according to an embodiment in the present disclosure may further include a substrate 1110, an insulating layer 1115, a hydrophobic layer 1130, a support layer 1140, a membrane layer 1150, a protective layer 1160, metal layers 1180 and 1190, and a cap 1210.

For example, the first and second bulk acoustic resonators 10a, 10b, 20a, and 20b may be disposed on a single substrate 1110. The substrate 1110 may be a silicon substrate. For example, a silicon wafer or a silicon on insulator (SOI) type substrate may be used as the substrate 1110. An insulating layer 1115 may be provided on an upper surface of the substrate 1110 to electrically isolate the substrate 1110 from the resonating unit 1120. In addition, the insulating layer 1115 may prevent the substrate 1110 from being etched by an etching gas when a cavity C or C1 is formed during a manufacturing process of an acoustic resonator. In this case, the insulating layer 1115 may be formed of any one or any combination of any two or more of silicon dioxide (SiO₂), silicon nitride (Si₃N4), aluminum oxide (Al₂O₃), and aluminum nitride (AlN), and may be formed through any one of chemical vapor deposition, RF magnetron sputtering, and evaporation.

The cavities C and C1 may be positioned between the substrate 1110 and the resonating unit 1120 and may be surrounded by the support layer 1140. The support layer 1140 may be formed on the insulating layer 1115, and inside the support layer 1140, the cavities C and C1 and an etch stopper 1145 are surrounded by the cavities C and C1 may be disposed on the periphery of the etch stopper 1145. The cavities C and C1 are formed as empty spaces, and may be formed by removing a portion of a sacrificial layer formed in the process of preparing the support layer 1140, and the support layer 1140 may be formed as a remaining portion of the sacrificial layer. For the support layer 1140, a material such as polysilicon or amorphous silicon that is easy to etch may be used. However, the present disclosure is not limited thereto. The etch stopper 1145 may be disposed along the boundary of the cavities C and C1. The etch stopper 1145 may be provided to prevent etching from proceeding beyond the cavity region during a cavity C and C1 formation process.

Depending on the design, the membrane layer 1150 may be disposed between the cavities C and C1 and the resonating unit 1120. The membrane layer 1150 may be formed of a material that is not easily removed in the process of forming the cavities C and C1. For example, when a halide-based etching gas such as fluorine (F) or chlorine (Cl) is used to remove a portion (e.g., a cavity region) of the support layer 1140, the membrane layer 1150 may be formed of a material having a low reactivity with the etching gas. In this case, the membrane layer 1150 may include either one or both of silicon dioxide (SiO₂) and silicon nitride (Si₃N₄). In addition, the membrane layer 1150 may be formed of a dielectric layer containing any one or any combination of any two or more of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), or a metal layer containing a material of any one or any combination of any two or more of aluminum (Al), nickel (Ni), chromium (Cr), platinum (Pt), gallium (Ga), and hafnium (Hf). However, the configuration of the present disclosure is not limited thereto.

The protective layer 1160 may be disposed along the surface of the resonating unit 1120 to protect the resonating unit 1120 from the outside. For example, the protective layer 1160 may include any one of silicon dioxide (SiO₂), silicon nitride (Si₃N4), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), zinc oxide (ZnO), amorphous silicon (a-Si), and polycrystalline silicon (p-Si), but is not limited thereto.

The hydrophobic layer 1130 may be disposed on the protective layer 1160 and serve to inhibit adsorption of water and hydroxyl groups (OH groups) to the protective layer 1160 or the resonating unit 1120, thereby minimizing frequency fluctuations and uniformly maintaining resonator performance. For example, the hydrophobic layer 1130 may be formed of a self-assembled monolayer (SAM) formation material rather than a polymer and may be formed by vapor-depositing a precursor that may have hydrophobicity. For example, the hydrophobic layer 1130 may include fluorine (F) or silicon (Si), and a fluorocarbon having a silicon head may be used, but is limited thereto. As the precursor, hydrocarbon having a silicon head or siloxane having a silicon head may be used, but is not limited thereto.

The first electrode 1121 and the second electrode 1125 may be formed of a conductor, and may be formed of, for example, gold, molybdenum, ruthenium, iridium, aluminum, platinum, titanium, tungsten, palladium, tantalum, chromium, nickel, or a material including at least one thereof, but is not limited thereto.

For example, the piezoelectric layers 1123 of the first and second bulk acoustic resonators 10a, 10b, 20a, and 20b may contain the same piezoelectric material. As a material of the piezoelectric layer 1123, zinc oxide (ZnO), aluminum nitride (AlN), doped aluminum nitride, lead zirconate titanate, quartz, or another piezoelectric material may be selectively used. The doped aluminum nitride may further include a rare earth metal, a transition metal, or an alkaline earth metal. The rare earth metal may include any one or any combination of any two or more of scandium (Sc), erbium (Er), yttrium (Y), and lanthanum (La). The transition metal may include any one or any combination of any two or more of hafnium (Hf), titanium (Ti), zirconium (Zr), tantalum (Ta), and niobium (Nb). The alkaline earth metal may also include magnesium (Mg). The content of elements doped into aluminum nitride (AlN) may be in the range of 0.1 to 30 at %. The piezoelectric layer may be formed by doping aluminum nitride (AlN) with scandium (Sc). In this case, a piezoelectric constant may be increased to increase the kt² of the acoustic resonator.

Depending on the design, the resonating unit 1120 may further include an insertion layer 1170. The insertion layer 1170 may be partially disposed near the edge of the resonating unit 1120 and have an inclined surface L so that acoustic impedance at the center S of the resonating unit 1120 and acoustic impedance at the edge E of the resonating unit 1120 are different from each other. For example, the insertion layer 1170 may be formed of a dielectric material such as silicon dioxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), or zinc oxide (ZnO), but may be formed of a material different from that of the piezoelectric layer 1123.

For example, when the material (e.g., AlN, ZnO, PZT) contained in the insertion layer 1170 has piezoelectricity as high as that of the piezoelectric material of the piezoelectric layer 1123, the thickness of the insertion layer 1170 may also be further added to the thicknesses T1 and T2 of the piezoelectric layer 1123. Alternatively, a spacing distance between the first electrode 1121 and the second electrode 1125 may be lengthened to be greater than the thicknesses T1 and T2 of the piezoelectric layer 1123 by the thickness of the insertion layer 1170.

The thickness T1 or thickness ratio T1/T3 of the piezoelectric layers of the first bulk acoustic resonators 10a and 10b may be higher than the thickness T2 or thickness ratio T2/T4 of the piezoelectric layers of the second bulk acoustic resonators 20a and 20b, and the thickness of the insertion layer 1170 of the first bulk acoustic resonators 10a and 10b may be the same as the thickness of the insertion layer 1170 of the second bulk acoustic resonators 20a and 20b. Accordingly, a spacing distance between the first electrode 1121 and the second electrode 1125 of the first bulk acoustic resonators 10a and 10b, and a spacing distance between the first electrode 1121 and the second electrode 1125 of the second bulk acoustic resonators 20a and 20b may be different from each other.

For example, the thicknesses T1 and T2 of the piezoelectric layer 1123 may be measured as an average of a thickness of a central portion 1123a of the piezoelectric layer 1123 in a central portion S of the resonating unit 1120, a thickness of an inclined portion 11231 of an edge portion 1123b (E) of the piezoelectric layer 1123 in an extension portion E of the resonating unit 1120, and a thickness of an extension portion 11232 of the edge portion 1123b.

Referring to FIG. 5B, a number of piezoelectric layers 1123c and 1123d of the first bulk acoustic resonator 10b may be greater than a number of piezoelectric layers 1123 of the second bulk acoustic resonator 20a. Accordingly, the difference in the thicknesses T1 and T2 of the first and second bulk acoustic resonators 10b and 20a may be implemented more efficiently.

For example, the piezoelectric layer 1123c of the first bulk acoustic resonator 10b and the piezoelectric layer 1123 of the second bulk acoustic resonator 20a may be simultaneously formed. Thereafter, the piezoelectric layer 1123d of the first bulk acoustic resonator 10b may be formed on the piezoelectric layer 1123c.

Referring to FIG. 5C, an overlapping area (proportional to the square of L1) of the first electrode 1121, the piezoelectric layer 1123, and the second electrode 1125 of the first bulk acoustic resonator 10a may be greater than an overlapping area (proportional to the square of L2) of the first electrode 1121, the piezoelectric layer 1123, and the second electrode 1125 of the second bulk acoustic resonator 20b. Accordingly, the withstand voltage, power durability, and/or heat dissipation performance of the first bulk acoustic resonator 10a may be further improved.

Referring to FIGS. 6A and 6B, the bulk acoustic resonator filters 100k and 100m according to embodiments in the present disclosure may further include a bump 1310, a connection pattern 1320, and a hydrophobic layer 1330. Each of first RF ports P1c and P1d and a second RF port may include a portion of the bump 1310 and a portion of the connection pattern 1320.

The bump 1310 may be connected between the electronic device substrate 90 and the connection pattern 1320 illustrated in FIGS. 4B and 4C, and may be disposed on a lower surface of the substrate 1110 or an upper surface of the cap 1210. For example, the bump 1310 may contain a metal material (e.g., Pb, Sn) having a melting point lower than a melting point of the connection pattern 1320, and may fix the acoustic resonator filters 100k and 100m to the electronic device substrate by a soldering process or a reflow process.

At least a portion of the connection pattern 1320 may pass through the substrate 1110 or the cap 1210 and may be electrically connected to at least one of the first and second electrodes 1121 and 1125. Accordingly, the resonating unit 1120 may be electrically connected to the outside of the bulk acoustic resonator filters 100k and 100m. For example, a portion of the substrate 1110 or the cap 1210 may be perforated, and the connection pattern 1320 may be formed on a side surface of the perforated portion in the substrate 1110 or the cap 1210 or may fill the perforated portion and may contain a metal material (e.g., gold, copper, titanium (Ti)-copper (Cu) alloy, etc.). For example, a portion of the connection pattern 1320 may have a pad shape in contact with the bump 1310.

The hydrophobic layer 1330 may contain the same material as the hydrophobic layer 1130, may be disposed on the lower surface of the substrate 1110 or the upper surface of the cap 1210, and may improve reliability of the bump 1310 and the connection pattern 1320. For example, the hydrophobic layer 1330 may reduce the adsorption of organic matter, moisture, and other foreign materials that may occur during the formation process of the bonding member 1220 to the connection pattern 1320, thereby reducing transmission loss in the connection pattern 1320.

Referring to FIGS. 6C and 6D, the bulk acoustic resonator filters 100n and 100o according to embodiments in the present disclosure may include the resonating unit 1120 disposed between the substrate 1110 and the cap 1210, the substrate 1110 may be disposed on a base substrate 1410, and the base substrate 1410 may be bonded to the cap 1210.

The area of the base substrate 1410 may be equal to or greater than that of the substrate 1110, so the base substrate 1410 may provide a larger area in which the resonating unit 1120 is disposed compared to the substrate 1110. For example, the bulk acoustic resonator filters 100n and 100o may be effective because the number of the resonating units 1120 disposed on the base substrate 1410 is greater, and thus may be more efficient in realizing a large-capacity structure.

Since the cap 1210 may be bonded to the base substrate 1410, a horizontal area of the cap 1210 may also be increased. For example, since the base substrate 1410 may contain a ceramic material, the base substrate 1410 may be implemented in a manner different from a wafer level package (WLP) method, and a bonding structure (e.g., an adhesive polymer) between the cap 1210 and the base substrate 1410 may also be different from the structure (e.g., a eutectic bonding structure or an anodic bonding structure) of a grounding member of the present disclosure. For example, the grounding member may be disposed in an area overlapping an area surrounded by the cap 1210 in a vertical direction, and may not provide a bonding force for the cap 1210.

For example, the base substrate 1410 may be thicker than the substrate 1110 to stably have a large horizontal area, and the cap 1210 may contain a metal material to stably have a large horizontal area, and a thermosetting resin such as an epoxy resin may bond the base substrate 1410 and the substrate 1110 to each other, but are not limited thereto.

Referring to FIGS. 6C and 6D, the bulk acoustic resonator filters 100n and 100o according to embodiments in the present disclosure may include the base substrate 1410, a connection pattern 1420, and a bonding wire 1490, and each of the first RF ports P1e and P1f and the second RF port may include a portion of the connection pattern 1420 and a portion of the bonding wire 1490.

The connection pattern 1420 may include a through via 1421 passing through the base substrate 1410 in a vertical direction and a pad 1422 disposed on a lower surface of the base substrate 1410 and may be formed in the same manner as the connection pattern 1320 illustrated in FIGS. 6A and 6B, but is not limited thereto.

The bonding wire 1490 may connect the connection pattern 1420 and the metal layers 1180 and 1190 to each other, and may contain the same metal material as a metal material included in the metal layers 1180 and 1190, but is not limited thereto.

Referring to FIG. 6D, the substrate 1110 and/or the resonating unit 1120 may be disposed in a recessed space of the base substrate 1410, and thus may be surrounded by the base substrate 1410. For example, the cap 1210 may have a plate shape having a constant thickness.

As set forth above, the bulk acoustic resonator filter and the bulk acoustic resonator filter module according to embodiments in the present disclosure may efficiently broaden a frequency band while securing a roll-off characteristic, a skirt characteristic, and/or an attenuation characteristic and efficiently improve a withstand voltage, power durability, and/or heat dissipation performance, so that a center frequency of the frequency band may be stably increased.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and are not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic resonator filter comprising:
a plurality of bulk acoustic resonators connected between a first radio frequency (RF) port and a second RF port to form a frequency band,
wherein each of the plurality of bulk acoustic resonators comprises a first electrode, a second electrode, and a piezoelectric layer disposed between the first and second electrodes,
the plurality of bulk acoustic resonators comprise at least one first bulk acoustic resonator and at least one second bulk acoustic resonator,
a difference between a resonant frequency and an antiresonant frequency of each of the at least one first bulk acoustic resonator is different from a difference between a resonant frequency and an antiresonant frequency of each of the at least one second bulk acoustic resonator, and
a ratio of a thickness of the piezoelectric layer to a total thickness of the first and second electrodes in each of the at least one first bulk acoustic resonator is different from a ratio of a thickness of the piezoelectric layer to a total thickness of the first and second electrodes in each of the at least one second bulk acoustic resonator, and/or the thickness of the piezoelectric layer of each of the at least one first bulk acoustic resonator is different from the thickness of the piezoelectric layer of each of the at least one second bulk acoustic resonator.

2. The bulk acoustic resonator filter of claim 1, wherein the at least one first bulk acoustic resonator comprises a first series bulk acoustic resonator electrically connected in series between the first and second RF ports,
the at least one second bulk acoustic resonator comprises a second series bulk acoustic resonator electrically connected in series between the first and second RF ports,
the plurality of bulk acoustic resonators further comprise at least one shunt bulk acoustic resonator electrically connected between the first and second series bulk acoustic resonators and a ground, and
a difference between the antiresonant frequencies of the first and second series bulk acoustic resonators is less than a difference between resonant frequencies of the first and second series bulk acoustic resonators.

3. The bulk acoustic resonator filter of claim 1, wherein the plurality of bulk acoustic resonators further comprise at least one series bulk acoustic resonator electrically connected in series between the first and second RF ports,
the at least one first bulk acoustic resonator comprises a first shunt bulk acoustic resonator electrically connected between the at least one series bulk acoustic resonator and a ground,
the at least one second bulk acoustic resonator comprises a second shunt bulk acoustic resonator electrically connected between the at least one series bulk acoustic resonator and the ground, and
a difference between the resonant frequencies of the first and second shunt bulk acoustic resonators is less than a difference between antiresonant frequencies of the first and second shunt bulk acoustic resonators.

4. The bulk acoustic resonator filter of claim 1, wherein the at least one first bulk acoustic resonator comprises a first series bulk acoustic resonator electrically connected in series between the first and second RF ports,
the at least one second bulk acoustic resonator comprises a second series bulk acoustic resonator electrically connected in series between the first and second RF ports;
the at least one first bulk acoustic resonator further comprises a first shunt bulk acoustic resonator electrically connected between a ground and either one or both of the first and second series bulk acoustic resonators, and
the at least one second bulk acoustic resonator further comprises a second shunt bulk acoustic resonator electrically connected between the ground and either one or both of the first and second series bulk acoustic resonators.

5. The bulk acoustic resonator filter of claim 4, wherein a difference between the antiresonant frequencies of the first and second series bulk acoustic resonators is less than a difference between resonant frequencies of the first and second series bulk acoustic resonators, and
a difference between the resonant frequencies of the first and second shunt bulk acoustic resonators is less than a difference between antiresonant frequencies of the first and second shunt bulk acoustic resonators.

6. The bulk acoustic resonator filter of claim 4, wherein each of the first and second shunt bulk acoustic resonators comprises an anti-series structure.

7. The bulk acoustic resonator filter of claim 1, wherein a number of the plurality of bulk acoustic resonators is three or more,
the at least one first bulk acoustic resonator comprises a first bulk acoustic resonator electrically connected closest to the first RF port among the plurality of bulk acoustic resonators, and
the at least one second bulk acoustic resonator comprises a second bulk acoustic resonator electrically connected closest to the second RF port among the plurality of bulk acoustic resonators.

8. The bulk acoustic resonator filter of claim 7, wherein a number of the plurality of bulk acoustic resonators is 5 or more,
the at least one first bulk acoustic resonator further comprises a first bulk acoustic resonator electrically connected second closest to the first RF port among the plurality of bulk acoustic resonators, and
the at least one second bulk acoustic resonator further comprises a second bulk acoustic resonator electrically connected second closest to the second RF port among the plurality of bulk acoustic resonators.

9. The bulk acoustic resonator filter of claim 1, wherein the at least one first bulk acoustic resonator and the at least one second bulk acoustic resonator are disposed on a single substrate.

10. The bulk acoustic resonator filter of claim 1, wherein a number of piezoelectric layers of each of the at least one first bulk acoustic resonator is different from a number of piezoelectric layers of each of the at least one second bulk acoustic resonators.

11. The bulk acoustic resonator filter of claim 1, wherein a piezoelectric material of the piezoelectric layer of each of the at least one first bulk acoustic resonator is the same as a piezoelectric material of the piezoelectric layer of each of the at least one second bulk acoustic resonator.

12. The bulk acoustic resonator filter of claim 1, wherein a spacing distance between the first electrode and the second electrode of each of the at least one first bulk acoustic resonator is different from a spacing distance between the first electrode and the second electrode of each of the at least one second bulk acoustic resonator.

13. The bulk acoustic resonator filter of claim 1, wherein the ratio of the thickness of the piezoelectric layer to the total thickness of the first and second electrodes in each of the at least one first bulk acoustic resonator is greater than the ratio of the thickness of the piezoelectric layer to the total thickness of the first and second electrodes in each of the at least one second bulk acoustic resonator, and/or the thickness of the piezoelectric layer of each of the at least one first bulk acoustic resonator is greater than the thickness of the piezoelectric layer of each of the at least one second bulk acoustic resonator, and
an overlapping area of the first electrode, the piezoelectric layer, and the second electrode of each of the at least one first bulk acoustic resonator is greater than an overlapping area of the first electrode, the piezoelectric layer, and the second electrode of each of the at least one second bulk acoustic resonator filter.

14. The bulk acoustic resonator filter of claim 1, wherein the ratio of the thickness of the piezoelectric layer to the total thickness of the first and second electrodes in each of the at least one first bulk acoustic resonator is greater than the ratio of the thickness of the piezoelectric layer to the total thickness of the first and second electrodes in each of the at least one second bulk acoustic resonator, and/or the thickness of the piezoelectric layer of each of the at least one first bulk acoustic resonator is greater than the thickness of the piezoelectric layer of each of the at least one second bulk acoustic resonator, and
each of the at least one first bulk acoustic resonator comprises an anti-parallel structure.

15. The bulk acoustic resonator filter of claim 1, wherein the frequency band covers a portion of a frequency range of 3 GHz or higher and 6 GHz or less.

16. The bulk acoustic resonator filter of claim 1, wherein the first RF port is electrically connected between the second RF port and a power amplifier,
the first bulk acoustic resonator is electrically connected between the first RF port and the second bulk acoustic resonator, and
the ratio of the thickness of the piezoelectric layer to the total thickness of the first and second electrodes in each of the at least one first bulk acoustic resonator is greater than the ratio of the thickness of the piezoelectric layer to the total thickness of the first and second electrodes in each of the at least one second bulk acoustic resonator, and/or the thickness of the piezoelectric layer of each of the at least one first bulk acoustic resonator is greater than the thickness of the piezoelectric layer of each of the at least one second bulk acoustic resonator.

17. A bulk acoustic resonator filter module comprising:
a first bulk acoustic resonator filter forming a first frequency band and comprising a first bulk acoustic resonator; and
a second bulk acoustic resonator filter forming a second frequency band and comprising a second bulk acoustic resonator,
wherein each of the first and second bulk acoustic resonators comprises a first electrode, a second electrode, and a piezoelectric layer disposed between the first and second electrodes,
a difference between a resonant frequency and an anti-resonant frequency of the first bulk acoustic resonator is greater than a difference between a resonant frequency and an anti-resonant frequency of the second bulk acoustic resonator, and
a ratio of a thickness of the piezoelectric layer to a total thickness of the first and second electrodes in the first bulk acoustic resonator is greater than a ratio of a thickness of the piezoelectric layer to a total thickness of the first and second electrodes in the second bulk acoustic resonator, and/or the thickness of the piezoelectric layer of the first bulk acoustic resonator is greater than the thickness of the piezoelectric layer of the second bulk acoustic resonator.

18. The bulk acoustic resonator filter module of claim 17, wherein the first bulk acoustic resonator filter and the second bulk acoustic resonator filter are configured so that a power of a first RF signal passing through the first bulk acoustic resonator filter is greater than a power of a second RF signal passing through the second bulk acoustic resonator filter.

19. The bulk acoustic resonator filter module of claim 17, wherein the first bulk acoustic resonator filter is electrically connected between a power amplifier and an antenna, and
the second bulk acoustic resonator filter is electrically connected to the antenna.

20. The bulk acoustic resonator filter module of claim 17, wherein the first bulk acoustic resonator filter further comprises a third bulk acoustic resonator,
the third bulk acoustic resonator comprises a first electrode, a second electrode, and a piezoelectric layer disposed between the first and second electrodes,
the first bulk acoustic resonator is electrically connected to the third bulk acoustic resonator so that a first RF signal passes through the first bulk acoustic resonator before the first RF signal passes through the third bulk acoustic resonator, and
the ratio of the thickness of the piezoelectric layer to the total thickness of the first and second electrodes in the first bulk acoustic resonator is greater than a ratio of a thickness of the piezoelectric layer to a total thickness of the first and second electrodes in the third bulk acoustic resonator, and/or the thickness of the piezoelectric layer of the first bulk acoustic resonator is greater than the thickness of the piezoelectric layer of the third bulk acoustic resonator.

21. The bulk acoustic resonator filter module of claim 20, wherein the second bulk acoustic resonator filter further comprises a fourth bulk acoustic resonator,
the fourth bulk acoustic resonator comprises a first electrode, a second electrode, and a piezoelectric layer disposed between the first and second electrodes,
the fourth bulk acoustic resonator is electrically connected to the second bulk acoustic resonator so that a second RF signal passes through the fourth bulk acoustic resonator before the second RF signal passes through the second bulk acoustic resonator, and
a ratio of a thickness of the piezoelectric layer to a total thickness of the first and second electrodes in the fourth bulk acoustic resonator is greater than the ratio of the thickness of the piezoelectric layer to the total thickness of the first and second electrodes in the second bulk acoustic resonator, and/or the thickness of the piezoelectric layer thickness of the fourth bulk acoustic resonator is greater than the thickness of the piezoelectric layer of the second bulk acoustic resonator.

22. The bulk acoustic resonator filter module of claim 21, wherein the ratio of the thickness of the piezoelectric layer to the total thickness of the first and second electrodes in the first bulk acoustic resonator is greater than the ratio of the thickness of the piezoelectric layer to the total thickness of the first and second electrodes in the fourth bulk acoustic resonator, and/or the thickness of the piezoelectric layer of the first bulk acoustic resonator is greater than the thickness of the piezoelectric layer of the fourth bulk acoustic resonator.

23. The bulk acoustic resonator filter module of claim 17, wherein the second bulk acoustic resonator filter further comprises a fourth bulk acoustic resonator,
the fourth bulk acoustic resonator comprises a first electrode, a second electrode, and a piezoelectric layer disposed between the first and second electrodes,
the fourth bulk acoustic resonator is electrically connected to the second bulk acoustic resonator so that a second RF signal passes through the fourth bulk acoustic resonator before the second RF signal passes through the second bulk acoustic resonator,
a ratio of a thickness of the piezoelectric layer to a total thickness of the first and second electrodes in the fourth bulk acoustic resonator is greater than the ratio of the thickness of the piezoelectric layer to the total thickness of the first and second electrodes in the second bulk acoustic resonator, and/or the thickness of the piezoelectric layer of the fourth bulk acoustic resonator is greater than the thickness of the piezoelectric layer of the second bulk acoustic resonator, and
the ratio of the thickness of the piezoelectric layer to the total thickness of the first and second electrodes in the first bulk acoustic resonator is greater than the ratio of the thickness of the piezoelectric layer to the total thickness of the first and second electrodes in the fourth bulk acoustic resonator, and/or the thickness of the piezoelectric layer of the first bulk acoustic resonator is greater than the thickness of the piezoelectric layer of the fourth bulk acoustic resonator.

24. The bulk acoustic resonator filter module of claim 17, wherein the first bulk acoustic resonator filter is electrically connected to a first power amplifier, and
the second bulk acoustic resonator filter is electrically connected to a second power amplifier.

25. The bulk acoustic resonator filter module of claim 17, wherein the first bulk acoustic resonator filter is electrically connected to a power amplifier, and
the second bulk acoustic resonator filter is electrically connected to a low noise amplifier.

26. The bulk acoustic resonator filter module of claim 17, wherein a center frequency of the first frequency band is higher than a center frequency of the second frequency band.
